(19) United States
(12) Patent Application Publication
(10) Pub. No.: US 2010/0059795 A1
(43) Pub. Date: Mar. 11, 2010

(54) VERTICAL CURRENT TRANSPORT IN A POWER CONVERTER CIRCUIT

(76) Inventor: Firas Azrai, Austin, TX (US)

Correspondence Address: ZAGORIN O'BRIEN GRAHAM LLP, 7600B NORTH CAPITAL OF TEXAS HIGHWAY, SUITE 350, AUSTIN, TX, 78731, US

(21) Appl. No.: 12/206,182

(22) Filed: Sep. 8, 2008

(51) Int. Cl. H01L 27/10; H01L 21/82

(52) U.S. Cl. 257/207; 438/128; 257/E27.07; 257/E21.606

(57) ABSTRACT

In at least one embodiment of the invention, an apparatus includes an integrated circuit comprising a power stage portion of a power converter circuit. The power stage portion includes a first switch circuit portion formed by a first plurality of lateral devices in a first substrate. The power stage portion includes a second switch circuit portion formed by a second plurality of lateral devices in the first substrate. The integrated circuit includes a multi-layer current routing structure configured to transport a first current between the first plurality of lateral devices and an array of conductor structures on the surface of the integrated circuit using a first substantially vertical conduction path when the first switch circuit portion is enabled. The multi-layer current routing structure is configured to transport a second current between the second plurality of lateral devices and the array of conductor structures using a second substantially vertical conduction path when the second switch portion is enabled.

### BACKGROUND

1. Field of the Invention

This application relates to integrated circuits and more particularly to power converter integrated circuits.

2. Description of the Related Art

Typical integrated circuit power devices are high-voltage devices that are manufactured vertically in a semiconductor substrate, e.g., field-effect transistor source and gate terminals (e.g., terminals 102 and 104, respectively of FIG. 1) are formed on a front-side of the semiconductor substrate and a drain terminal (e.g., terminal 106) is formed on a back-side of the semiconductor substrate allowing current to flow vertically between the front-side and the back-side of the semiconductor substrate. However, typical integrated circuit power devices manufacturing processes are not conducive to the manufacture of digital control logic or low voltage, mixed-signal circuits. A separate controller integrated circuit, manufactured using a typical complementary metal-oxide semiconductor (CMOS) process that includes laterally formed devices (i.e., devices including source, gate, and drain terminals formed in a first surface of a substrate and configured to conduct current laterally across the first surface of a substrate), may be coupled to the power devices integrated circuit. In a typical application, the power devices integrated circuit is coupled to the controller integrated circuit on a printed circuit board substrate (e.g., via wire bonding) and/or coupled to other circuit elements, and encapsulated with a mold compound to form a multi-chip module (FIG. 2).

### SUMMARY

In at least one embodiment of the invention, an apparatus includes an integrated circuit comprising a power stage portion of a power converter circuit. The power stage portion includes a first switch circuit portion formed by a first plurality of lateral devices in a first substrate. The power stage portion includes a second switch circuit portion formed by a second plurality of lateral devices in the first substrate. The integrated circuit includes a multi-layer current routing structure configured to transport a first current between the first plurality of lateral devices and an array of conductor structures on the surface of the integrated circuit using a first substantially vertical conduction path when the first switch circuit portion is enabled. The multi-layer current routing structure is configured to transport a second current between the second plurality of lateral devices and the array of conductor structures using a second substantially vertical conduction path when the second switch portion is enabled.

In at least one embodiment of the invention, a method includes vertically transporting first currents between an array of conductor structures on a surface of an integrated circuit on a first substrate and a first switch circuit portion of a power converter circuit formed by at least a first plurality of lateral devices in the first substrate, when the first switch portion is enabled. The method includes vertically transporting second currents between the array of conductor structures and a second switch circuit portion of the power converter circuit formed by at least a second plurality of lateral devices in the first substrate, when the second switch portion is enabled.

In at least one embodiment of the invention, a method of manufacturing a power converter circuit includes forming an integrated circuit including a first power stage portion of the power converter circuit on an integrated circuit. The forming the integrated circuit includes forming in a first substrate a first switch circuit portion including a first plurality of lateral devices and includes forming in the first substrate a second switch circuit portion including a second plurality of lateral devices. The forming the integrated circuit includes forming an array of conductor structures on the surface of the integrated circuit. The forming the integrated circuit includes forming a multi-layer current routing structure configured to transport a first current between the first plurality of lateral devices and the array of conductor structures using a first substantially vertical conduction path when the first switch circuit portion is enabled. The multi-layer current routing structure is configured to transport a second current between the second plurality of lateral devices and the array of conductor structures using a second substantially vertical conduction path when the second switch portion is enabled.

### BRIEF DESCRIPTION OF THE DRAWINGS

The present invention may be better understood, and its numerous objects, features, and advantages made apparent to those skilled in the art by referencing the accompanying drawings.

FIG. 1 illustrates an exemplary integrated circuit power device including at least one vertically formed device.

FIG. 2 illustrates an exemplary multi-chip module including the exemplary integrated circuit power device of FIG. 1.

FIG. 3 illustrates an exemplary power stage circuit portion, including a high-side device and a low-side device consistent with at least one embodiment of the invention.

FIG. 4 illustrates exemplary signal waveforms for the power stage circuit portion of FIG. 3 consistent with at least one embodiment of the invention.

FIG. 5 illustrates an exemplary power stage circuit portion, including a high-side device and a plurality of low-side devices consistent with at least one embodiment of the invention.

FIG. 6 illustrates an exemplary layout of a power stage circuit portion, including a driver circuit portion and a switch circuit portion consistent with at least one embodiment of the invention.

FIG. 7 illustrates an exemplary layout of a portion of a power stage circuit portion including driver circuits distributed amongst switch circuits consistent with at least one embodiment of the invention.

FIG. 8 illustrates an exemplary layout of two switches of a power stage circuit portion consistent with at least one embodiment of the invention.

FIG. 9 illustrates exemplary structures associated with a first integrated circuit layer of a vertical transport structure consistent with at least one embodiment of the invention.

FIG. 10 illustrates exemplary structures associated with a second integrated circuit layer of a vertical transport structure consistent with at least one embodiment of the invention.

FIG. 11 illustrates exemplary structures associated with a third integrated circuit layer of a vertical transport structure consistent with at least one embodiment of the invention.

FIG. 12 illustrates exemplary structures associated with a fourth integrated circuit layer of a vertical transport structure consistent with at least one embodiment of the invention.

FIG. 13 illustrates exemplary structures on a surface of an integrated circuit consistent with at least one embodiment of the invention.

FIG. 14 illustrates exemplary interconnect structures consistent with at least one embodiment of the invention.

FIG. 15 illustrates exemplary structures associated with electrical contacts coupled to the structures of FIG. 14 consistent with at least one embodiment of the invention.

FIG. 16 illustrates an exemplary packaging technique for a module including a power converter circuit consistent with at least one embodiment of the invention.

FIG. 17 illustrates an exemplary integrated circuit layout for a power converter circuit consistent with at least one embodiment of the invention.

FIG. 18 illustrates an exemplary integrated circuit layout for a power converter circuit consistent with at least one embodiment of the invention.

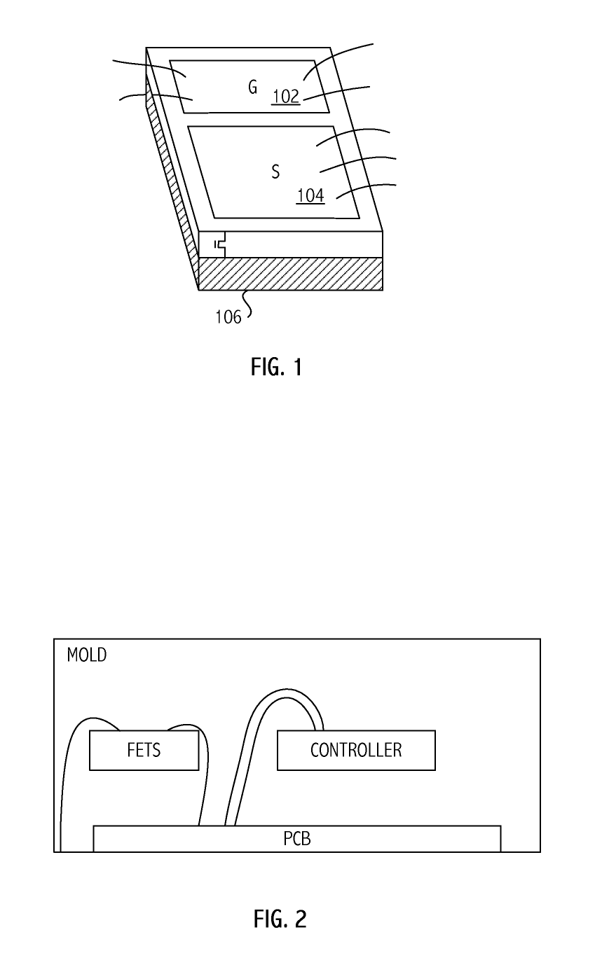

The use of the same reference symbols in different drawings indicates similar or identical items.

### DESCRIPTION OF THE PREFERRED EMBODIMENT(S)

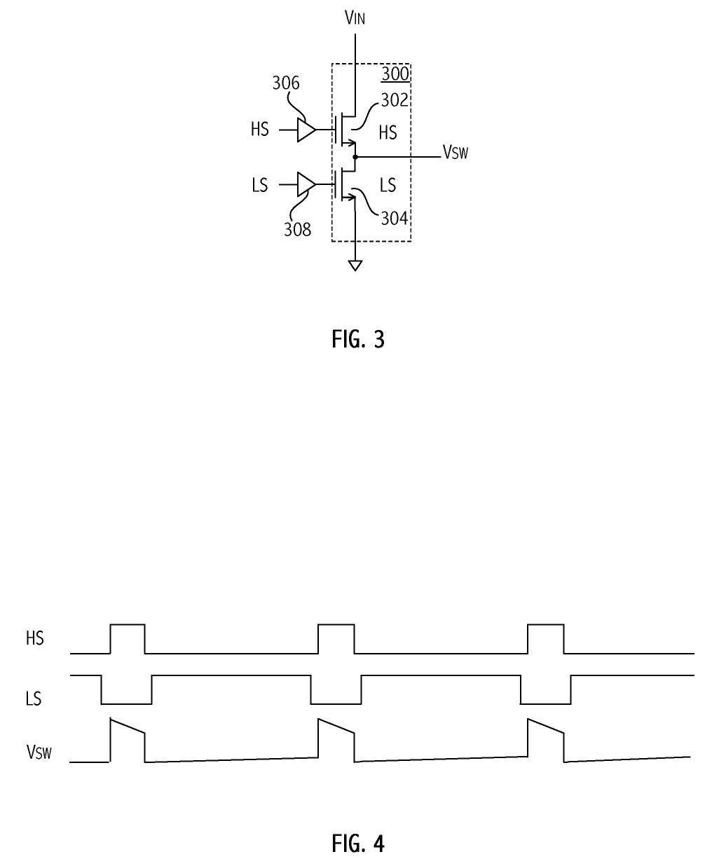

Referring to FIG. 3, a portion of a power stage circuit includes a high-side device 302 and a low-side device 304. The high-side and low-side devices provide paths to V_{IN} and ground, respectively, for a switch node with a switch voltage (V_{SW} ), which in at least one embodiment of a power stage circuit is coupled to a node of an inductor. Note that the devices 302 and 304 are relatively large and may be implemented by a number (e.g., thousands) of individual devices. Drivers 306 and 308 provide sufficient drive capability for controlling the gates of the devices 302 and 304, respectively. In at least one embodiment of a power converter circuit, a pulse-width modulated signal generated by a corresponding pulse-width modulator circuit is provided to a non-overlap generator circuit (not shown), which generates the HS and LS signals and guarantees that the high-side and low-side devices are not on at the same time. Drivers 306 and 308 may be implemented by a number of separate driver circuits, which may be independently controlled. Although circuit portion 300 is illustrated showing only devices of a single conductivity type (e.g., n-type devices), other embodiments may include devices of other conductivity types (e.g., at least one p-type device or at least one n-type device and at least one p-type device). Power stage circuit portion 300 and drivers 306 and 308 may be included in a power converter circuit, e.g., a power converter circuit disclosed in provisional application for patent, application No. 61/094,750, filed Sep. 5, 2008, entitled “Integrated Multiple Output Power Conversion System,” naming Firas Azrai, Eric J. King, Eric Smith, David A. Boles, Arthur T. Kimmel, Alfredo R. Linz, and Damir Spanjol as inventors, which application is hereby incorporated by reference.

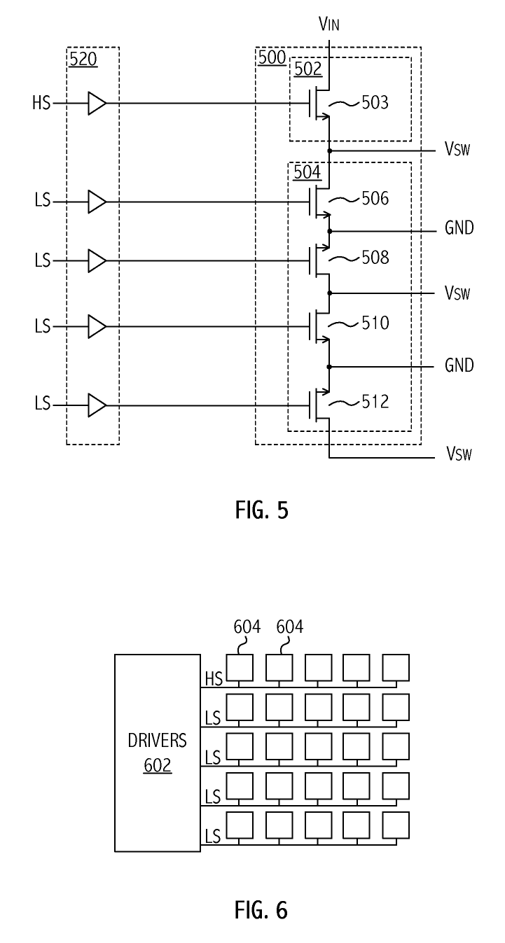

Referring to FIG. 4, in at least one application, the low-side circuit and the high-side circuit are not enabled for the same period of time. Accordingly, the number of devices forming the high-side circuit and the low-side circuit may differ to reduce the resistance of circuit portions that are enabled longer. For example, the low-side circuit is enabled for a period of time that is greater than the period of time for which the high-side circuit is enabled. Accordingly, referring to FIG. 5, in an embodiment of a power converter circuit, low-side circuit 504 includes a greater number of devices than the number of devices (e.g., four times the number of devices) included in high-side circuit 502. The devices of low-side circuit 504 are coupled in parallel to reduce the resistance of the low-side circuit. Note that the ratio of the number of devices included in the low-side circuit to the number of devices included in the high-side circuit may vary and techniques described herein are applicable to low-side and high-side circuits having other numbers of devices.

In at least one embodiment of switch circuit 500, high-side circuit 502 and low-side circuit 504 each can conduct currents of approximately 1.5 Amperes to approximately 5 Amperes in response to V_{IN} in the range of approximately 3 V to approximately 16 V. To manufacture low-side and high-side devices capable of conducting such currents in a typical semiconductor process (e.g., devices on the order of 10 milli-Ohms (mΩ) MOSFET structures), high-side device 503 and low-side circuit 504 are formed by thousands of individual lateral MOSFET devices. Those individual lateral MOSFET devices are coupled together by conductor structures to operate as one large switch device, e.g., high-side device 503 or low-side devices 506, 508, 510, or 512.

The gate terminals of switch circuit portion (e.g., switch circuit 300 and switch circuit 500 of FIGS. 3 and 5, respectively) are driven by appropriate ones of one or more high-side signal and one or more low-side signal, which are provided by corresponding driver circuits (e.g., by driver circuits 306 and 308 to switch circuit portion 300 and by driver circuits 520 to switch circuit portion 500). In at least one embodiment of a power converter circuit, the driver circuits are laid out adjacent to a corresponding array of switch circuit devices. For example, referring to FIG. 6, drivers 602 are laid out adjacent to the array of switch circuit devices that form switch 500 of FIG. 5 and drivers 602 are coupled to the switch devices (e.g., devices 604) using lateral routing (i.e., routing that conducts current across the surface of the substrate). The lateral routing between the driver circuits and the switch circuits results in drive delay because switch signals travel across different distances. Thus, individual devices of the switch circuit may not be driven at the same time.

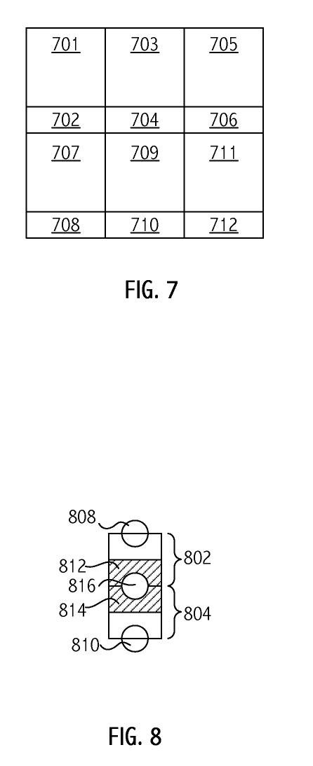

In at least one embodiment of a power converter circuit, a technique for reducing the transport distance and drive delay associated with conductors coupling driver circuits and associated switch circuits includes distributing the driver circuits throughout an array of corresponding switch circuit devices. Referring to FIG. 7, in at least one embodiment of a power converter circuit, an individual driver circuit drives two adjacent devices. For example, driver circuit 702 drives both device 701 and device 707 at the same time, while device 707 is also concurrently driven by driver circuit 708. Similarly, driver circuits 740 and 706 concurrently drive both devices 703 and 709 and both devices 705 and 711, respectively, while driver circuits 709 and 711 are concurrently driven by driver circuits 710 and 712, respectively.

Referring to FIG. 8, in at least one embodiment of a power converter circuit, terminals of individual devices are consolidated and one conductive contact is coupled to consolidate terminals of two separate devices, as illustrated by the exemplary layout of two adjacent devices (e.g., device 802 and device 804). Individual devices 802 and 804 may be two low-side devices, two high-side devices, or a low-side device and a high-side device. Note that a terminal of each device is combined into a single terminal coupled to both devices. For example, assuming that device 802 and device 804 are low-side device 506 and low-side device 508 of FIG. 5, respectively, source terminal 812 of low-side device 506 and source terminal 814 of low-side device 508 are each coupled to conductor 816, which corresponds to GND. Conductor 808 corresponds to V_{SW} and conductor 810 corresponds to another V_{SW} terminal.

Since conductors in a typical semiconductor manufacturing process are very thin (e.g., less than approximately 1 μm), those conductors are highly resistive (e.g., approximately 80 mΩ per square). Those conductors increasingly dissipate power as a distance of transport in those conductors increases. Note that switch devices may be coupled to devices that are a substantial distance away on an integrated circuit, or off-chip. Accordingly, reducing the transport distance in the conductors of the typical semiconductor manufacturing process between the pluralities of individual lateral MOSFET devices forming high-side device 502 and low-side circuit 504 and the terminals of switch circuit portion 500 reduces resistive losses resulting therefrom.

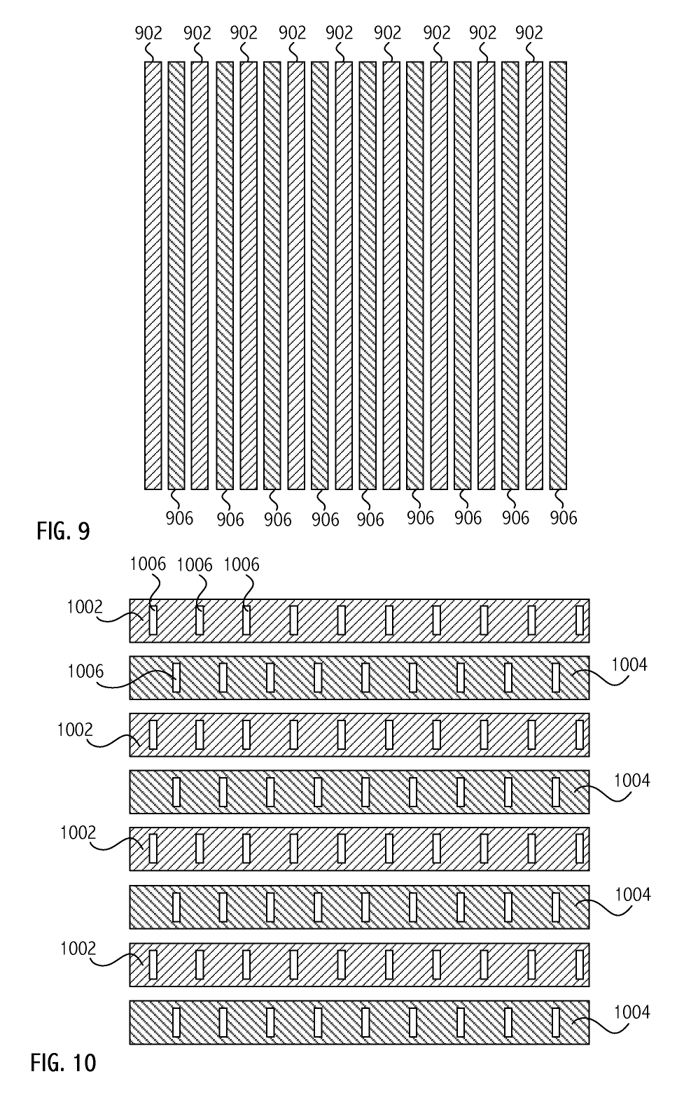

A technique for reducing the resistive losses of the path between terminals of individual lateral MOSFET devices forming switch devices and a device coupled to the switch node (e.g., an inductor or other suitable device) includes reducing lateral current transport in highly resistive conductors of the integrated circuit. The technique includes an exemplary vertical current transport structure that reduces resistive losses attributed to current transport in high resistance conductors. The technique includes at least one lateral current transport structure formed in a conductor having a lower resistance than the conductor of the integrated circuit manufactured by a typical semiconductor manufacturing process. FIGS. 9-13 illustrate techniques for vertical current transport including forming a substantially vertical current path from individual MOSFET devices to terminals (e.g., V_{SW}, V_{IN}, and GND) of switch circuit 500, which are then coupled together laterally in a conductor having a lower resistance than the conductor of the typical semiconductor manufacturing process.

Referring to FIG. 9, an exemplary portion of a plurality of individual lateral MOSFET devices forming high-side device 502 or low-side circuit 504 on a semiconductor substrate includes source terminals (e.g., source terminals 902) and drain terminals (e.g., drain terminals 906) corresponding to a plurality of individual devices. Source terminals 902 and drain terminals 906 are formed by alternating, substantially parallel conductor strips formed in a first layer (e.g., metal-1) of a typical semiconductor manufacturing process. As referred to herein, a layer of a typical semiconductor manufacturing process includes conductor and insulator portions formed by typical semiconductor manufacturing techniques. As referred to herein, a conductor is a metal (e.g., aluminum, copper, or other suitable metal) or other electrically conductive material (e.g., polysilicon or other suitable electrically conductive material). In at least one embodiment of switch circuit 500, gate terminals (not shown) of the plurality of individual lateral MOSFET devices forming high-side device 503 or low-side circuit 504 are coupled by other conductor structures to nearby circuits (e.g., individual driver circuits of the integrated circuit, as discussed above). In an embodiment, the conductor strips of the first conductor layer are approximately 1.5 μm wide. Note that individual ones of conductor strips 902 and 906 are electrically isolated from each other in the first layer.

Referring to FIG. 10, substantially parallel conductor strips, formed in a second layer (e.g., metal-2) above the first layer, include electrical contacts to conductive vias (e.g., vias 1006) that couple conductor strips of the second layer to conductor strips of the first layer. The substantially parallel conductor strips of the second layer extend in a direction with respect to a surface of the substrate forming the integrated circuit substantially orthogonal to the direction in which substantially parallel conductor strips of the first conductor layer extend. The substantially parallel conductor strips of the second layer are substantially wider than the parallel conductor strips of the first layer. For example, in at least one embodiment, the conductor strips of the second conductor layer are approximately 10 μm wide, as compared to approximately 1.5 μm wide conductor strips of the first layer. Alternating ones of the plurality of conductor strips of the second conductor layer are electrically coupled to corresponding ones of source and drain terminals in the first conductor layer. For example, conductor strips 1002 electrically couple together source terminals 902 in the first conductor layer and conductor strips 1004 are coupled to drain terminals 906 in the first conductor layer. Note that the conductor strips 1002 electrically consolidate currents associated with a plurality of individual devices into a single associated conductor path from multiple source terminals of the first conductor layer. In an embodiment, vias 1006 are each formed by a plurality of individual vias (e.g., approximately 20-30 vias) contacting corresponding ones of conductor strips 1002 or conductor strips 1004. Note that individual ones of conductor strips 1002 and 1004 are electrically isolated from each other in the second layer. In at least one embodiment of a power converter circuit, multiple conductor strips in the second layer may be coupled to a particular conductor structure of the layer below, thereby reducing lateral current flow.

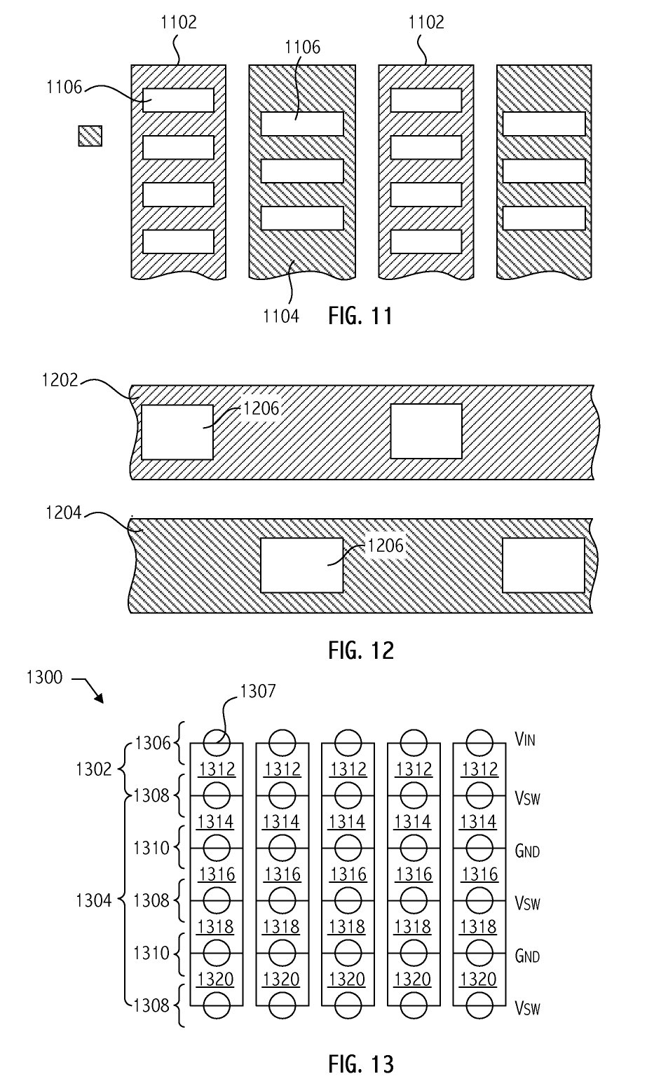

Referring to FIG. 11, substantially parallel conductor strips formed in a third layer (e.g., metal-3) above both the first and the second layers include electrical contacts (e.g., contacts 1106) to conductive vias that couple conductor strips of the third layer to conductor strips of the second layer. The substantially parallel conductor strips of the third layer extend in a direction with respect to a surface of the substrate forming the integrated circuit substantially orthogonal to the direction in which substantially parallel conductor strips of the second conductor layer extend. The substantially parallel conductor strips of the third layer are substantially wider than the parallel conductor strips of the second layer. For example, in an embodiment, the conductor strips of the third conductor layer are approximately 30 μm wide, as compared to approximately 10 μm wide conductor strips of the second layer and approximately 1.5 μm wide conductor strips of the first layer. Alternating ones of the plurality of conductor strips of the third conductor layer are electrically coupled to corresponding pluralities of source-coupled and drain-coupled conductor strips of the second layer. For example, conductor strips 1102 electrically couple together conductor strips 1002 in the second layer and conductor strips 1104 couple together conductor strips 1004 in the second conductor layer. Note that conductor strips 1102 electrically consolidate currents associated with a plurality of individual conductor paths of the second conductor layer into a single conductor path of the third conductor layer. In an embodiment, vias 1106 are each formed by a plurality of individual vias connecting corresponding ones of conductor strips 1102 or 1104. Note that individual ones of conductor strips 1102 and 1104 are electrically isolated from each other in the third layer. In at least one embodiment of a power converter circuit, multiple conductor strips in the third layer may be coupled to a particular conductor structure of the layer below, thereby reducing lateral current flow.

Referring to FIG. 12, substantially parallel conductor strips formed in a fourth layer (e.g., metal-4) above the first, second, and third layers include electrical contacts (e.g., contacts 1206) to conductive vias that couple conductor strips of the fourth layer to conductor strips of the third layer. The substantially parallel conductor strips of the fourth layer extend in a direction with respect to a surface of the substrate forming the integrated circuit substantially orthogonal to the direction in which substantially parallel conductor strips of the third conductor layer extend. The substantially parallel conductor strips of the fourth layer are substantially wider than the parallel conductor strips of the third layer. For example, in an embodiment, the conductor strips of the fourth conductor layer are approximately 80 μm wide, as compared to approximately 30 μm wide conductor strips of the third layer, approximately 10 μm wide conductor strips of the second layer, and approximately 1.5 μm wide conductor strips of the first layer. One or more pairs of conductor strips of the fourth conductor layer are electrically coupled to separate pluralities of the conductor strips of the third conductor layer corresponding to source and drain terminals. Note that conductor strips 1202 and 1204 electrically consolidate currents from multiple conductor paths of the third conductor layer into respective conductor paths of the fourth conductor layer. In an embodiment, vias 1206 are each formed from a sea of vias (e.g., thousands of vias) contacting corresponding ones of conductor strips 1202 or 1204. Note that individual ones of conductor strips 1202 and 1204 are electrically isolated from each other in the fourth layer. In at least one embodiment of a power converter circuit, multiple conductor strips in the fourth layer may be coupled to a particular conductor structure of the layer below, thereby reducing lateral current flow. Although embodiments are described as including four integrated circuit layers, the techniques described herein are applicable to conductor structures formed in additional integrated circuit layers.

Referring to FIGS. 13 and 5, an exemplary layout of contacts to terminals of an exemplary switch circuit 500 includes a high-side layout portion 1302 and a low-side layout portion 1304. Contacts in adjacent columns are configured to be coupled to the same electrical potential and contacts in adjacent rows are configured to be coupled to different electrical potentials, e.g., consistent with the terminals of switch circuit 500. For example, contacts in row 1306 couple terminals of switch circuit 500 to V_{IN}, contacts in rows 1308 couple terminals of switch circuit 500 to V_{SW}, and contacts in rows 1310 couple terminals of switch circuit 500 to GND. Note that the designation of row and column for an array of contacts is arbitrary and the layout may vary accordingly. For example, a layout consistent with another embodiment of switch circuit 500 includes contacts in adjacent rows configured to be coupled to the same electrical potential and contacts in adjacent columns configured to be coupled to different electrical potentials. In at least one embodiment of a power converter circuit, individual ones of contacts in rows 1306, 1308, and 1310 are physically isolated from each other and from others of contacts in rows 1306, 1308, and 1310 on the surface of the integrated circuit. For example, row 1306 includes a plurality of contacts in separate columns coupled to drain terminals in corresponding sets of devices.

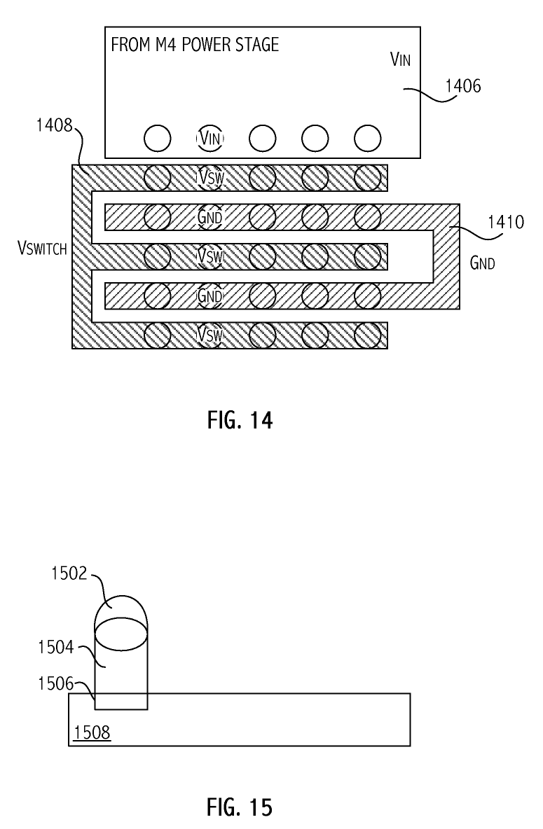

Low-side layout portion 1304 includes a plurality of rows of low-side devices configured consistent with the low-side circuit 504 of FIG. 5. For example, e.g., rows including low-side devices 1314, 1316, 1318, and 1320 correspond to low-side devices 506, 508, 510, and 512, respectively. Note that in the row including low-side devices 1314 current flow between V_{SW} and GND flows in a direction opposite to the current flow between V_{SW} and GND in the adjacent row of low-side devices, i.e., the row including low-side devices 1316. Similarly, current flow between V_{SW} and GND in the row including low-side devices 1316 flows in a direction opposite to the current flow between V_{SW} and GND in the row including low-side devices 1318, which flows in a direction opposite to the current flow between V_{SW} and GND in the row including low-side devices 1320. That configuration of low-side devices facilitates use of the conductor structure described below with regard to FIG. 14. However, in other embodiments of a power converter circuit, other suitable device layout configurations are used with other suitable conductor structures.

Referring to FIGS. 13 and 14, individual ones of contacts in rows 1306, 1308, and 1310 are coupled to others of contacts 1306, 1308, and 1310, respectively, by corresponding conductor structures 1406, 1408, and 1410. In at least one embodiment of switch circuit 500, contacts 1306 are coupled to V_{IN} by conductor structure 1406. Contacts 1308 and contacts 1310 are coupled to V_{SW} and GND, respectively, via interdigitated conductor structures 1408 and 1410, respectively. In at least one embodiment, individual contacts, which are physically isolated in the top layer of a first substrate, are coupled together by a relatively low resistance conductor on a second substrate. For example, contacts 1306, 1308, and 1310 are pads, or are coupled to pads, on a first substrate and conductor structures 1406, 1408, and 1410 are formed from a low resistance conductor (e.g., 32 μm thick copper) on a second substrate. A structure for coupling contacts 1306, 1308, and 1310 to corresponding conductor structures 1406, 1408, and 1410 on the second substrate includes conductor pillars. Referring to FIG. 15, a contact (e.g., pad 1506) on the first substrate (e.g., 1508), is coupled to a conductor 1504, which may be a conductive ball or conductive cylinder formed from copper (e.g., a 100 μm diameter copper cylinder) or other suitable conductor material. In at least one embodiment of conductor 1504, the conductive cylinder is coupled to the second substrate by connecting structure 1502, which may be formed from solder or other conductive connecting material.

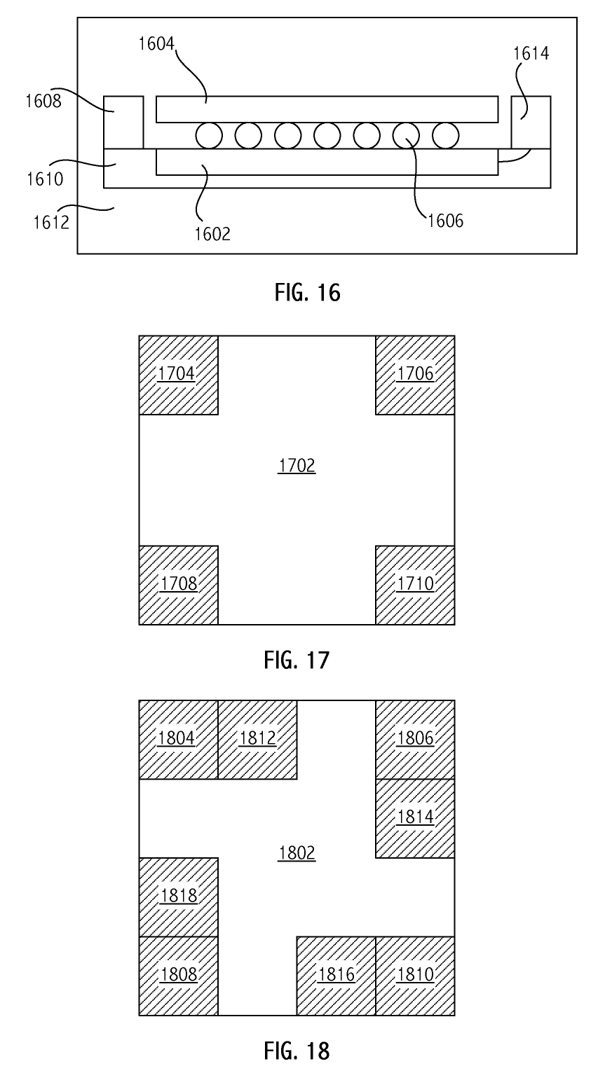

Referring to FIG. 16, a first substrate (e.g., substrate 1604) including a switch circuit, vertical current transport structure, and contacts coupled thereto, is flip-chip attached to a second substrate (e.g., substrate 1610) via conductor structures (e.g., structures 1606). The second substrate, which includes conductor structures (e.g., conductor structures 1602) for coupling individual nodes of the switch circuit (e.g., an array of contacts corresponding to V_{IN}, V_{SW}, and GND of switch circuit 500 of FIG. 5), may be a multi-layer printed circuit board (e.g., BT laminate) or other suitable substrate. Referring back to FIG. 16, in at least one embodiment, the second substrate is coupled to one or more discrete components, e.g., inductor 1608, capacitor 1614, or other suitable components. In at least one embodiment of a power converter circuit, the first substrate, second substrate, and any other components coupled thereto, are encapsulated by a mold compound (e.g., 1612) or other suitable material to form a multi-chip module.

Referring to FIG. 17, in at least one embodiment of a power converter circuit, a plurality of arrays of switch circuit portions are formed on an integrated circuit substrate. For example, switch circuit portions 1704, 1706, 1708, and 1710 correspond to individual power stage switch circuit arrays. Analog and digital circuitry used to control those power stages is integrated in the substrate, e.g., in region 1702. In at least one embodiment of the power converter circuit, the design of switch circuit portions facilitates integrating a transposed replica of the individual switch circuit portions onto the substrate to increase the current flow provided by the switch circuit, but maintain a substantially fixed power efficiency (FIG. 18). For example, if switch circuit portion 1704 has a resistance of x and provides a current of y, a switch circuit portion including a transposed replica of switch circuit portion 1704 coupled to the switch circuit portion (e.g., switch circuit portion formed by switch circuit portions 1804 and 1812) has a resistance of ½x and provides a current of 2y.

While circuits and physical structures are generally presumed, it is well recognized that in modern semiconductor design and fabrication, physical structures and circuits may be embodied in computer-readable descriptive form suitable for use in subsequent design, test or fabrication stages. Structures and functionality presented as discrete components in the exemplary configurations may be implemented as a combined structure or component. The invention is contemplated to include circuits, systems of circuits, related methods, and computer-readable medium encodings of such circuits, systems, and methods, all as described herein, and as defined in the appended claims. As used herein, a computer-readable medium includes at least disk, tape, or other magnetic, optical, semiconductor (e.g., flash memory cards, ROM), or electronic medium.

The description of the invention set forth herein is illustrative, and is not intended to limit the scope of the invention as set forth in the following claims. For example, note that switch circuit 500 is exemplary only and other switch circuit configurations using different numbers and types of high-side and low-side switches may be used. Variations and modifications of the embodiments disclosed herein may be made based on the description set forth herein, without departing from the scope and spirit of the invention as set forth in the following claims.

What is claimed is:

1. An apparatus comprising:
an integrated circuit comprising:
a power stage portion of a power converter circuit comprising:
a first switch circuit portion formed by a first plurality of lateral devices in a first substrate; and
a second switch circuit portion formed by a second plurality of lateral devices in the first substrate; and
a multi-layer current routing structure configured to transport a first current between the first plurality of lateral devices and an array of conductor structures on the surface of the integrated circuit using a first substantially vertical conduction path when the first switch circuit portion is enabled and configured to transport a second current between the second plurality of lateral devices and the array of conductor structures using a second substantially vertical conduction path when the second switch portion is enabled.

2. The apparatus as recited in claim 1, wherein the integrated circuit further comprises:
a digital control circuit formed in the first substrate and coupled to the power stage circuit portion.

3. The apparatus as recited in claim 1, wherein each successive integrated circuit layer of the multi-layer current routing structure consolidates a plurality of individual current conduction paths of a previous layer into a consolidated current conduction path, each successive layer being adjacent to the previous layer, the previous layer being between the successive layer and the first substrate.

4. The apparatus as recited in claim 1,
wherein the multi-layer current routing structure comprises a plurality of integrated circuit layers, each integrated circuit layer including a first plurality of conductor portions, a second plurality of conductor portions, and insulator layer portions electrically isolating individual conductor portions of the first and second pluralities of conductor portions,
wherein the first and second pluralities of conductor portions of a first semiconductor layer of the plurality of semiconductor layers includes a first plurality of vertical structures coupled to corresponding first terminals of the plurality of the first devices and a second plurality of vertical structures coupled to corresponding second terminals of the plurality of the second devices, and
wherein corresponding first and second pluralities of conductor portions of successive adjacent semiconductor layers of the plurality of semiconductor layers electrically couple together individual conductor portions of the first and second pluralities of conductor portions, respectively, of the next adjacent layer between an individual one of the successive adjacent semiconductor layers and the first substrate.

5. The apparatus as recited in claim 4,
wherein the top layer of the plurality of semiconductor layers, comprises the array of conductor structures,
wherein conductor structures in individual rows of the array of conductor structures correspond to individual components of a same signal and adjacent conductor structures in individual columns of the array of conductor structures correspond to individual components of different signals.

6. The apparatus as recited in claim 5, wherein the individual conductor structures of the array of conductor structures correspond to one of a first power supply terminal, a second power supply terminal, and an output power terminal.

7. The apparatus as recited in claim 5, further comprising:
a second substrate comprising at least one conductor pattern configured to couple together at least some of the individual conductor structures of the array of conductor structures and configured to route current between the individual conductor structures and a corresponding one of a first power supply terminal, a second power supply terminal, and a third node.

8. The apparatus as recited in claim 1, wherein the first plurality of lateral devices are of the same conductivity type and formed in a plurality of rows, lateral devices of an individual row of the plurality of rows conducting current in a direction, with respect to the surface of the integrated circuit, opposite to a direction of current conduction in a next adjacent row of the first plurality of devices when the plurality of devices are enabled.

9. The apparatus as recited in claim 1, further comprising:
a first conductor structure coupled to a first node and a first plurality of conductor structures of the array of conductor structures; and
a second conductor structure coupled to a second node and a second plurality of conductor structures of the array of conductor structures,
wherein the second conductor structure is interdigitated with the first conductor structure and electrically isolated from the first conductor structure.

10. The apparatus as recited in claim 1, wherein the power stage portion further comprises distributed driver circuit portions formed in the first substrate between at least a first row of lateral devices and a second row of lateral devices, and coupled to drive terminals of lateral devices in the first and second rows of lateral devices.

11. The apparatus as recited in claim 1,
wherein the first and second switch portions form a first power stage cell configured to provide a first output current and have a first resistance,
wherein the integrated circuit further comprises an additional power stage cell adjacent to the power stage cell, the additional power stage cell being a replicated and transposed version of the first power stage cell, and
wherein the first power stage cell and the additional power stage cell are configured to collectively provide twice the first output current and collectively have half the first resistance, thereby maintaining a substantially constant power efficiency.

12. A method of manufacturing a power converter circuit comprising:
forming an integrated circuit including a first power stage portion of the power converter circuit, wherein forming the integrated circuit comprises:
forming in a first substrate a first switch circuit portion including a first plurality of lateral devices; and
forming in the first substrate a second switch circuit portion including a second plurality of lateral devices;
forming an array of conductor structures on a surface of the integrated circuit; and
forming a multi-layer current routing structure configured to transport a first current between the first plurality of lateral devices and the array of conductor structures using a first substantially vertical conduction path when the first switch circuit portion is enabled and configured to transport a second current between the second plurality of lateral devices and the array of conductor structures using a second substantially vertical conduction path when the second switch portion is enabled.

13. The method, as recited in claim 12, wherein forming the integrated circuit further comprises:
forming an additional, transposed power stage portion on the integrated circuit adjacent to the first power stage portion, the transposed, power stage portion and the first power stage portion being electrically coupled in parallel, thereby increasing the power provided by the power converter circuit and reducing the resistance of the power converter circuit from the resistance of the first power stage portion.

14. The method, as recited in claim 12, wherein forming the multi-layer current routing structure comprises:
forming successive integrated circuit layers of the multi-layer current routing structure coupled to consolidate a plurality of individual current conduction paths of a previous layer into a consolidated current conduction path, each successive layer being adjacent to the previous layer, the previous layer being between the successive layer and the first substrate.

15. The method, as recited in claim 12, wherein forming the multi-layer current routing structure comprises:
forming a plurality of integrated circuit layers, each integrated circuit layer including a first plurality of conductor portions, a second plurality of conductor portions, and insulator layer portions electrically isolating individual conductor portions of the first and second pluralities of conductor portions,
wherein the first and second pluralities of conductor portions of a first semiconductor layer of the plurality of semiconductor layers includes a first plurality of vertical structures coupled to corresponding first terminals of the plurality of the first devices and a second plurality of vertical structures coupled to corresponding second terminals of the plurality of the second devices,
wherein corresponding first and second pluralities of conductor portions of successive adjacent semiconductor layers of the plurality of semiconductor layers electrically couple together respective individual conductor portions of the first and second pluralities of conductor portions, respectively, of the next adjacent layer between an individual one of the successive adjacent semiconductor layers and the first substrate.

16. The method, as recited in claim 15,
wherein the top layer of the plurality of semiconductor layers, comprises the array of conductor structures,
wherein conductor structures in individual rows of the array of conductor structures correspond to individual components of a same signal and adjacent conductor structures in individual columns of the array of conductor structures corresponding to individual components of different signals.

17. The method as recited in claim 16, wherein the individual conductor structures of the array of conductor structures correspond to one of a first power supply terminal, a second power supply terminal, and an output power terminal.

18. The method, as recited in claim 16, further comprising:
forming at least one conductor pattern on a second substrate, the conductor pattern being configured to couple together at least some of the individual conductor structures of the array of conductor structures and configured to route current between the individual conductor structures and a corresponding one of a first power supply terminal, a second power supply terminal, and a third node.

19. The method, as recited in claim 12, wherein forming the power stage portion comprises forming driver circuit portions distributed in the first substrate between at least a first row of lateral devices and a second row of lateral devices, and coupled to drive terminals of lateral devices in the first and second rows of lateral devices.

20. The method, as recited in claim 12,
wherein the first plurality of lateral devices are of the same conductivity type and are formed in a plurality of rows,
wherein lateral devices of an individual row of the plurality of rows are configured to conduct current in a direction, with respect to the surface of the integrated circuit, opposite to a direction of current conduction of lateral devices in a next adjacent row of the first plurality of devices when the plurality of devices are enabled.

21. The method, as recited in claim 20, further comprising:
forming a first conductor structure configured to couple a first node and a first plurality of conductor structures of the array of conductor structures; and
forming a second conductor structure configured to couple a second node and a second plurality of conductor structures of the array of conductor structures,
wherein the second conductor structure is interdigitated with the first conductor structure and electrically isolated from the first conductor structure.

22. A method comprising:
vertically transporting first currents between an array of conductor structures on a surface of an integrated circuit formed on a first substrate and a first switch circuit portion of a power converter circuit formed by at least a first plurality of lateral devices in the first substrate, when the first switch portion is enabled; and
vertically transporting second currents between the array of conductor structures and a second switch circuit portion of the power converter circuit formed by at least a second plurality of lateral devices in the first substrate, when the second switch portion is enabled.

23. The method as recited in claim 22, wherein the individual conductor structures of the array of conductor structures correspond to one of a first power supply terminal, a second power supply terminal, and an output power terminal.

24. The method, as recited in claim 22, wherein at least one of the vertically transporting the first and second currents comprises:
gradually consolidating currents from electrically isolated current paths by conductive portions in successive integrated circuit layers on the substrate, consolidation increasing in individual layers as corresponding distances of the individual layers from the substrate increases.

25. The method, as recited in claim 22, further comprising:
vertically transporting current from at least one individual conductor structure of the array of conductor structures through a corresponding conductor structure coupled to a conductor on a second substrate.

26. The method, as recited in claim 25, further comprising:
consolidating currents from a plurality of individual conductor structures of the array by the conductor on the second substrate.

27. The method, as recited in claim 25, further comprising:
laterally transporting the current across the second substrate to a first node.

28. The method, as recited in claim 22, further comprising:
uniformly driving individual lateral devices of the first plurality of lateral devices at substantially the same time; and
uniformly driving individual lateral devices of the second plurality of lateral devices at substantially the same time.

29. The method as recited in claim 22,
wherein individual lateral devices of the first plurality of lateral devices are of the same conductivity type and are formed in a plurality of rows, and
wherein individual lateral devices of an individual row of the plurality of rows conduct current in a direction, with respect to the surface of the integrated circuit, opposite to a direction of current conduction in a next adjacent row of the plurality of rows when the plurality of lateral devices are enabled.

30. The method as recited in claim 29,
wherein a first conductor structure is coupled to a first node and a first plurality of conductor structures of the array of conductor structures; and
a second conductor structure coupled to a second node and a second plurality of conductor structures of the array of conductor structures,
wherein the second conductor structure is interdigitated with the first conductor structure and electrically isolated from the first conductor structure.

31. An apparatus comprising:
a first switch portion of a power converter circuit;
a second switch portion of the power converter circuit;
a plurality of conductor means; and
vertical transport means for vertically transporting current between the first switch portion and the plurality of conductor means when the first switch portion is enabled and for vertically transporting current between the second switch portion and the plurality of conductor meanswhen the second switch portion is enabled.

32. The apparatus, as recited in claim 31, further comprising:
lateral transport means coupled to a first node and the plurality of conductor means,
wherein the first and second switch portions and the plurality of conductor means are formed in a first substrate, and
wherein the first node and the lateral transport means are formed on a second substrate.
